(19) United States
(12) Patent Application Publication
(10) Pub. No.: US 2026/0357133 A1
(43) Pub. Date: Nov. 12, 2026

(54) NANOPARTICLES OF BLUE LIGHT-EMITTING MATERIAL HAVING A PEROVSKITE-LIKE STRUCTURE AND IMPROVED PHOTOLUMINESCENT QUANTUM YIELD, AND METHOD OF PREPARING SAME

(71) Applicant: IUCF-HYU (IND-UNIV.COOPERATION FOUNDATION HANYANG UNIVERSITY), Seoul (KR)

(72) Inventors: Won Bin IM, Seoul (KR); Viswanath NOOLU SRINIVASA MANIKANTA, Seoul (KR); Tuhin SAMANTA, Seoul (KR); Sung Woo JANG, Seoul (KR)

(21) Appl. No.: 19/142,397

(22) PCT Filed: Dec. 22, 2023
(86) PCT No.: PCT/KR2023/021505

§ 371 Date: Jun. 23, 2025

(30) Foreign Application Priority Data
Dec. 23, 2022 (KR) 10-2022-0183665

(51) Int. Cl. C09K 11/77; B82Y 20/00; C01F 17/36; H10K 50/115

(52) U.S. Cl. CPC C09K 11/7705; C01F 17/36; H10K 50/115; B82Y 20/00; C01P 2002/72; C01P 2002/76; C01P 2004/04; C01P 2004/10; C01P 2004/54; C01P 2004/62; C01P 2006/60

(57) ABSTRACT

Nanoparticles of a blue light-emitting material represented by Chemical Formula 1, which has an emission peak wavelength in a range of 380 nm to 500 nm, upon being excited by an excitation source of 250 nm to 400 nm, and an average particle size of less than 1 micrometer, and a method of preparing the nanoparticles of the blue light-emitting material are provided:
Chemical Formula 1:

AMX₄
in Chemical Formula 1, A includes Li, Na, K, Rb, Cs, Mg, Ca, Sr, Ba, or a combination thereof, M includes Sc, Y, Al, Gd, Lu, or a combination thereof, and X includes O, F, Cl, Br, I, or a combination thereof.

### TECHNICAL FIELD

This relates to nanoparticles of blue light-emitting material having a perovskite-like structure and exhibiting excellent light-emitting efficiency, and a method of preparing the nanoparticles of blue light-emitting material.

### BACKGROUND ART

Blue phosphor materials used in LEDs, etc. require properties such as high color purity and/or thermal stability. Examples of currently known blue phosphor materials include CaWO₄ phosphors emitting a wavelength of about 400 nm to about 420 nm, MgWO₄ phosphors emitting a wavelength of about 480 nm, etc., and Pb (lead) is used as an activator. In the case of these phosphors, since light is emitted from the activator doped in the host, there is a problem that they have a wide fluorescence spectrum (i.e., low color purity) and contain lead (Pb), which is harmful to the human body. Another example of a blue phosphor material is a BaMaAl₁₀O₁₇:Eu²⁺ phosphor that uses Eu²⁺ ion as an activator, but this also tends to contain a lot of light in green region, which leads to low color purity, and has low thermal stability that limits the lifespan of the phosphor.

Compounds having a perovskite structure with the structural formula AMX₃ (A is a cation, M is a metal cation, and X is an anion) are being used in various fields, such as, for example, a display, a light-emitting diode, a solar cell, a photodetector, a laser, and the like, due to their high quantum yield, large absorption coefficient, and tunable band gap characteristics. Although the perovskite structure shows excellent optical properties including high luminescence efficiency, it is necessary to overcome the toxicity of divalent cations such as Pb and Sb as metal cations.

### DISCLOSURE

### Technical Problem

An embodiment provides nanoparticles of a novel blue luminescent material having high color purity, excellent thermal stability, and superior luminescent efficiency.

Another embodiment provides a method of preparing the nanoparticles of the novel blue light-emitting material.

Still another embodiment provides a light-emitting device including the nanoparticles of the blue light-emitting material.

### Technical Solution

An embodiment provides nanoparticles of a blue light-emitting material represented by Chemical Formula 1, the blue light-emitting material has an emission peak wavelength in a range of 380 nanometers (nm) to 500 nm, upon being excited by an excitation source having a wavelength range of 250 nm to 400 nm, and an average particle diameter of less than 1 micrometer (μm):

### Chemical Formula 1

AMX₄
in Chemical Formula 1,
A includes Li, Na, K, Rb, Cs, Mg, Ca, Sr, Ba, or a combination thereof,
M includes Sc, Y, Al, Gd, Lu, or a combination thereof, and
X includes O, F, Cl, Br, I, or a combination thereof.

The nanoparticles of the blue light-emitting material include needle-like particles.

The needle-like particles have an aspect ratio of greater than 1 and less than or equal to 100.

The nanoparticles of a blue light-emitting material have an average particle size of greater than 200 nanometers (nm) and less than or equal to 800 nm.

The nanoparticles of a blue light-emitting material have a photoluminescent quantum yield (PLQY) of 80% or more.

In Chemical Formula 1,

A includes Rb, Cs, Sr, Ba, or a combination thereof,

M includes Sc, Y, Al, or a combination thereof, and

X includes F, Cl, Br, or a combination thereof.

Chemical Formula 1 may be represented by Chemical Formula 2 or Chemical Formula 3:

### Chemical Formula 2

(A₁₋ₓBₓ)(M_{1-y}N_{y})X₄

### Chemical Formula 3

(A₁₋₂ₓBx)(M_{1-y}N_{y})X₄
in Chemical Formula 2 and Chemical Formula 3,
A includes Rb,
B includes Li, Na, K, Cs, Mg, Ca, Sr, Ba, or a combination thereof,
M includes Sc,
N includes Y, Al, Gd, Lu, or a combination thereof,
X includes O, F, Cl, Br, I, or a combination thereof, and
x is 0.01≤x≤0.10, and y is 0.01≤y≤0.10.

In Chemical Formula 2 and Chemical Formula 3, B may include Cs, and X may include F, and at least one of O, Cl, Br, of I.

In Chemical Formula 2 and Chemical Formula 3, X may include F and O.

The nanoparticles of a blue light-emitting material have an orthorhombic structure of Cmcm, and diffraction angles (2θ) of a first intensity peak and a second intensity peak, which is lower than the first intensity peak, in a range of 20≤2θ≤30, in an X-ray diffraction pattern.

The nanoparticles of the blue light-emitting material have a diffraction angle (2θ) of the first intensity peak in a range of 26.2≤2θ≤28.2, and a diffraction angle (2θ) of the second intensity peak in a range of 25.8≤2θ≤27.8, in the X-ray diffraction pattern.

The nanoparticles of the blue light-emitting material may be represented by RbScF_{4.}

Another embodiment provides a method of preparing nanoparticles of a blue light-emitting material, the method includes:
mixing a halide of Li, Na, K, Rb, Cs, Mg, Ca, Sr, Ba, or a combination thereof, and a halide of Sc, Y, Al, Gd, Lu, or a combination thereof to form a mixture;
heating the mixture at a temperature of from 500 °C to 600 °C under a strongly reducing atmosphere to form a heated material;
sintering the heated material at a temperature of from 600 °C to 700 °C under a strongly reducing atmosphere to form a sintered material; and
cooling and pulverizing the sintered material, adding an acidic solution thereto, and subjecting to ultrasonication.

The heating or the sintering under a strongly reducing atmosphere include heating the mixture or sintering the material with magnesium powder, titanium powder, or a combination thereof.

The method further includes separating nanoparticles by centrifugation, after performing the ultrasonication.

The method further includes pulverizing the mixture prior to the heating, or pulverizing the mixture prior to the heating and pulverizing the heated material after the heating.

The acidic solution includes an aqueous solution of an acid or a mixture of an acid and an alcohol.

The acid includes hydrochloric acid, sulfuric acid, phosphoric acid, hydrofluoric acid, nitric acid, or a combination thereof.

Another embodiment provides a light-emitting device including nanoparticles of a blue light-emitting material according to an embodiment.

The light-emitting device includes a first electrode and a second electrode facing each other, and a light-emitting layer disposed between the first electrode and the second electrode, wherein in the light-emitting layer includes nanoparticles of a blue light-emitting material according to an embodiment.

### Advantageous Effect

The nanoparticles of a blue light-emitting material according to an embodiment are lead-free blue light-emitting phosphors, which have a superior quantum efficiency (PLQY) to the conventional lead-free blue light-emitting phosphors, and may be advantageously applied to various light-emitting devices, such as, for example, light-emitting diodes (LEDs), solar cells, photovoltaics, sensors, color filters, and the like, without environmental issues, as they are prepared as nanoparticles.

### DESCRIPTION OF DRAWING

FIG. 1 is a graph showing X-ray diffraction patterns of bulk RbScF₄ particles (upper graph) having a particle size of several tens of micrometers prepared in a reference example and RbScF₄ nanoparticles (lower graph) having a particle size of several hundred nanometers prepared in Example 1.

FIG. 2 is a high-resolution transmission electron microscopy (HR-TEM) image of RbScF₄ nanoparticles prepared by sonication for 1 hour after addition of the acid solution in Example 1.

FIG. 3 shows a lattice pattern corresponding to the (002) plane of the RbScF₄ nanoparticles of FIG. 2, and the square in FIG. 2 shows a fast Fourier transform (FFT) pattern of the (002) plane.

FIG. 4 shows an electron diffraction pattern in a selected area of the RbScF₄ nanoparticles of FIG. 2.

FIG. 5 is a TEM image of the RbScF₄ nanoparticles of FIG. 2, and a TEM image showing the mapping of Ru, Sc, and F elements.

FIG. 6 is a TEM image of bulk RbScF₄ particles manufactured in a reference example.

FIG. 7 is a TEM image of RbScF₄ nanoparticles prepared in Example 1 by adding an acid solution to the bulk RbScF₄ particles prepared in a Reference Example, and then ultrasonicating them for 10 minutes.

FIG. 8 is a TEM image of RbScF₄ nanoparticles prepared in Example 1 by adding an acid solution to the bulk RbScF₄ particles prepared in a Reference Example, and then ultrasonicating them for 1 hour.

FIG. 9 is a TEM image of RbScF₄ nanoparticles prepared by adding an acid solution to the bulk RbScF₄ particles prepared in Reference Example, and then ultrasonicating them for 4 hours.

FIG. 10 is an enlarged photograph of a portion of FIG. 6.

FIG. 11 is a TEM image of RbScF₄ particles prepared by adding only ethanol without acid to the bulk RbScF₄ particles prepared in Reference Example, and then ultrasonicating them for 10 minutes.

FIG. 12 is a TEM image of RbScF₄ particles prepared in Example 2 by adding a mixed solution of acid and ethanol to the bulk RbScF₄ particles prepared in a Reference Example, and then ultrasonicating them for 10 minutes.

FIG. 13 is a TEM image of RbScF₄ particles prepared in Example 2 by adding a mixed solution of acid and ethanol to the bulk RbScF₄ particles prepared in a Reference Example, and then ultrasonicating them for 1 hour.

FIG. 14 is a TEM image of RbScF₄ particles prepared by adding a mixed solution of acid and ethanol to the bulk RbScF₄ particles prepared in a Reference Example, and then ultrasonicating them for 4 hours.

FIG. 15 is a TEM image of RbScF₄ particles prepared by adding a solution of ethanol and hexane to which oleylamine, which is alkaline, instead of an acid, is added, to the bulk RbScF₄ particles prepared in a Reference Example, and then ultrasonicating them for 10 minutes.

FIG. 16 shows graphs comparing the absorption characteristic of bulk RbScF₄ particles prepared according to a Reference Example and RbScF₄ nanoparticles according to Example 1, which is prepared by adding an acidic aqueous solution to the bulk RbScF₄ particles according to the Reference Example and ultrasonicating the same for 1 hour.

FIG. 17 shows graphs comparing the luminescence characteristic of bulk RbScF₄ particles according to a Reference Example and RbScF₄ nanoparticles according to Example 1, which is prepared by adding an acidic aqueous solution to the bulk RbScF₄ particles according to the Reference Example and ultrasonicating the same for 1 hour.

FIG. 18 shows graphs comparing the absorption characteristic of bulk RbScF₄ particles according to a Reference Example and RbScF₄ particles according to Example 2, which is prepared by adding a mixed solution of an acid and ethanol to the bulk RbScF₄ particles according to the Reference Example and ultrasonicating the same for 1 hour.

FIG. 19 shows graphs comparing the luminescence characteristic of bulk RbScF₄ particles according to a Reference Example and RbScF₄ nanoparticles according to Example 2, which is prepared by adding a mixed solution of an acid and ethanol to the bulk RbScF₄ particles according to the Reference Example and ultrasonicating the same for 1 hour.

FIG. 20 shows graphs comparing the absorption characteristic of bulk RbScF₄ particles according to a Reference Example, and RbScF₄ particles according to Example 1, which is prepared by adding an acidic solution to the bulk RbScF₄ particles according to the Reference Example and ultrasonicating the same for 30 minutes, 1 hour, and 2 hours, respectively.

FIG. 21 shows graphs comparing the luminescence characteristic of bulk RbScF₄ particles according to a Reference Example, and RbScF₄ nanoparticles according to Example 1, which is prepared by adding an acidic solution to the bulk RbScF₄ particles according to the Reference Example and ultrasonicating the same for 30 minutes, 1 hour, and 2 hours, respectively.

### BEST MODEL

Lead-free (Pb-free) perovskite materials have been known to have low quantum yields (PLQY) due to their low absorption coefficients. In addition, the device characteristics using the lead-free perovskite materials are very low compared to those of lead-based materials. The performance, stability, and efficiency of the lead-free perovskite materials are still lower due to their low PLQY values than lead-based perovskite materials. Therefore, there is a need to improve the quantum efficiency of the lead-free perovskite materials.

Recent studies have shown that the lead-free perovskite materials, such as Cs₃CuI₅, (C₉NH₂₀)₂SnBr₄, etc., have excellent luminescence properties, such as, for example, high photoluminescence quantum yields (PLQY) of 90% and 46%, respectively, and high exciton binding energies (Eb), compared to lead-based perovskites, such as, for example, CsPbX₃ (X=Cl, Br, I). However, the oxidation of Sn²⁺ or Cu⁺ ions in air, and the instability of organic components to moisture and heat limit the practical applications of the materials, and there are still remaining issues to be improved.

Meanwhile, the above-mentioned lead-free perovskite materials are bulk-sized materials with particle sizes of several tens of micrometers. Such bulk-sized materials are difficult to apply to light-emitting devices, etc. Therefore, there is a demand for a light-emitting material with particle sizes reduced to nanometers without deteriorating the luminescence properties of the lead-free perovskite materials.

The inventors of the present application have developed nanoparticles of a novel blue light-emitting material, which is a lead-free layered perovskite-like material, having an emission peak wavelength in a wavelength range of 380 nm to 500 nm, upon being excited by an excitation source having a wavelength range of 250 nm to 400 nm, and an average particle size of less than 1 micrometer (μm), thereby completing the present invention. The nanoparticles of the blue light-emitting material may be represented by Chemical Formula 1:

### Chemical Formula 1

AMX₄
in Chemical Formula 1,
A includes Li, Na, K, Rb, Cs, Mg, Ca, Sr, Ba, or a combination thereof,
M includes Sc, Y, Al, Gd, Lu, or a combination thereof, and
X includes O, F, Cl, Br, I, or a combination thereof.

In Chemical Formula 1, A may include Rb, Cs, Sr, Ba, or a combination thereof, M may include Sc, Y, Al, or a combination thereof, and X may include F, Cl, Br, or a combination thereof.

Chemical Formula 1 may be represented by Chemical Formula 2 or Chemical Formula 3:

### Chemical Formula 2

(A₁₋ₓBₓ)(M_{1-y}N_{y})X₄

### Chemical Formula 3

(A₁₋₂ₓBₓ)(M_{1-y}N_{y})X₄
in Chemical Formula 2 and Chemical Formula 3,
A may include Rb,
B may include Li, Na, K, Cs, Mg, Ca, Sr, Ba, or a combination thereof,
M may include Sc,
N may include Y, Al, Gd, Lu, or a combination thereof,
X may include O, F, Cl, Br, I, or a combination thereof, and
x may be 0.01≤x≤0.10, and y may be 0.01≤y≤0.10.

In Chemical Formula 2 and Chemical Formula 3, B may include Cs, and X may include F, and one or more of O, Cl, Br, and I, for example, X may include F and O.

The nanoparticles of the blue light-emitting material may include needle-like particles, wherein an aspect ratio of the needle-like particles may be greater than 1 and less than or equal to 100. Here, the ‘aspect ratio’ may mean a ratio of the length of the major axis to the length of the minor axis of the needle-like particles. The aspect ratio of the needle-like particles may be, for example, about 5 to 100, for example, about 5 to 90, about 5 to 80, about 10 to 80, about 10 to 70, about 10 to 60, about 10 to 50, about 10 to 45, about 10 to 40, about 10 to 30, about 10 to 25, or about 10 to 20, but is not limited thereto.

The average particle size of the nanoparticles of the blue light-emitting material according to an embodiment may be less than 1 micrometer, for example, about 950 nanometers (nm) or less, for example, about 900 nm or less, about 800 nm or less, about 750 nm or less, about 700 nm or less, about 650 nm or less, about 600 nm or less, about 550 nm or less, about 500 nm or less, about 450 nm or less, about 400 nm or less, about 350 nm or less, about 300 nm or less, about 250 nm or less, about 200 nm or less, about 150 nm or less, or about 100 nm or less. The average particle size of the nanoparticles of the blue light-emitting material according to an embodiment may be, for example, about 50 nm to about 900 nm, about 50 nm to about 850 nm, about 50 nm to about 800 nm, about 100 nm to about 750 nm, about 100 nm to about 700 nm, about 100 nm to about 650 nm, about 100 nm to about 600 nm, about 100 nm to about 550 nm, about 100 nm to about 500 nm, about 100 nm to about 450 nm, about 100 nm to about 400 nm, about 100 nm to about 350 nm, or about 100 nm to about 300 nm, about 100 nm to about 250 nm, or about 100 nm to about 200 nm, but is not limited to the ranges.

The quantum efficiency (PLQY: Photoluminescent Quantum Yield) of the nanoparticles of the above blue light-emitting material is 80% or more. For example, the quantum efficiency of the nanoparticles of the above blue light-emitting material may be 85% or more, for example, 88% or more, or 90% or more.

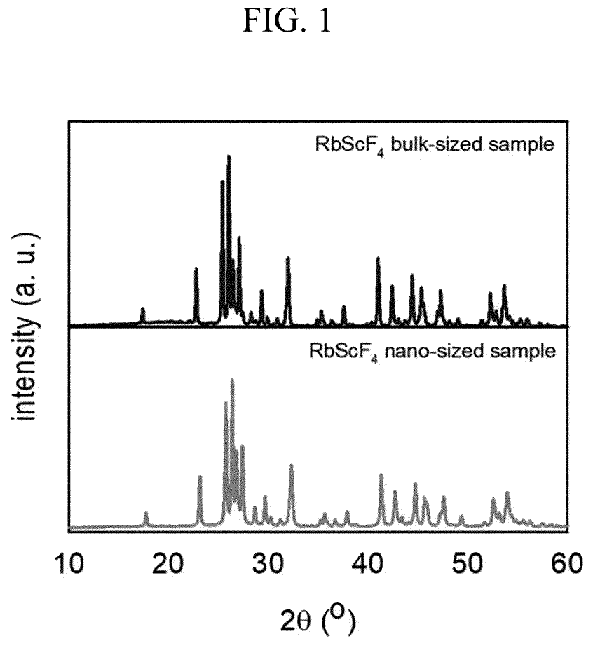

The blue light-emitting material represented by Chemical Formula 1 has an orthorhombic structure of Cmcm in bulk state with particle size of tens of micrometers or more, and as can be seen from the upper graph of the X-ray diffraction patterns of FIG. 1, the diffraction angles (2θ) of the first intensity peak and the second intensity peak, which is lower than the first intensity peak, may be positioned in a range of 20≤2θ≤30. For example, the blue light-emitting material represented by Chemical Formula 1 in bulk state may have the first intensity peak positioned in a diffraction angle (2θ) of 26.2≤2θ≤28.2, and the second intensity peak positioned in a diffraction angle (2θ) of 25.8≤2θ≤27.8, in the X-ray diffraction pattern.

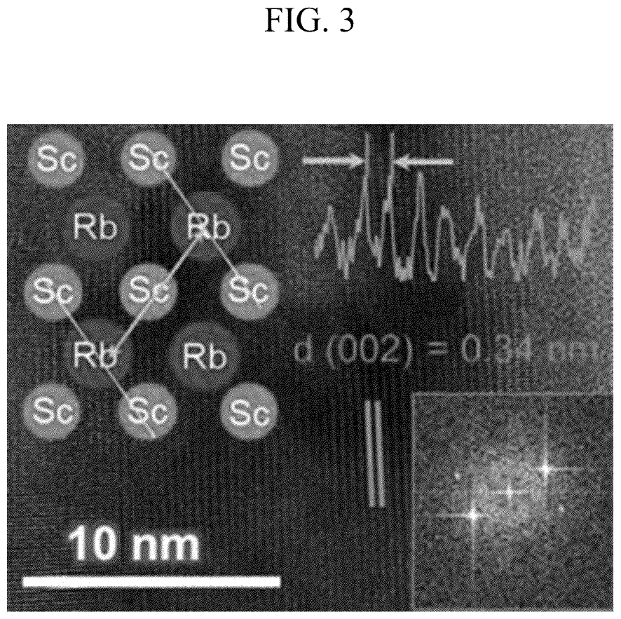

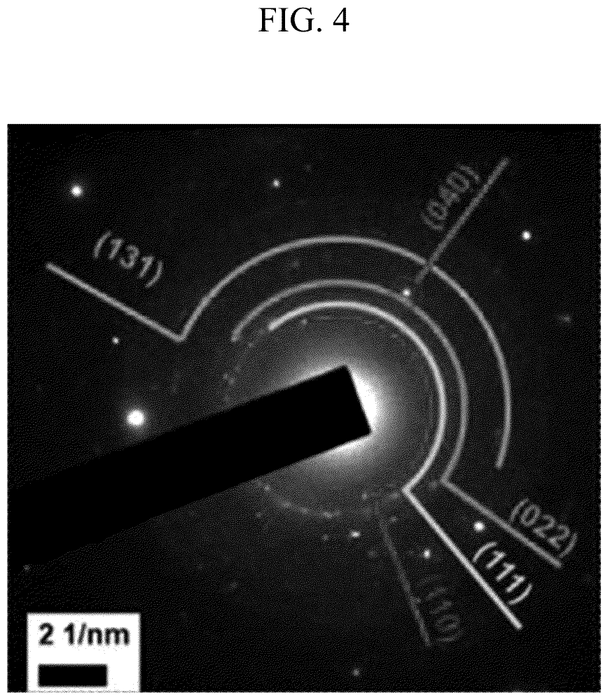

The nanoparticles of the blue light-emitting material according to an embodiment have an X-ray diffraction pattern shown in the lower graph of FIG. 1. As can be seen by comparing the upper and lower graphs of FIG. 1, the X-ray diffraction pattern of the bulk state of the blue light-emitting material represented by Chemical Formula 1 and the X-ray diffraction pattern of the nanoparticles of the material are almost the same. That is, the nanoparticles of the blue light-emitting material represented by the chemical formula 1, whose particle size is reduced to a nanometer unit according to an embodiment, have the same basic crystal structure as the particles of the bulk state of the blue light-emitting material represented by the Chemical Formula 1. This fact can also be confirmed from FIG. 3. FIG. 3 shows a lattice pattern image of the (002) plane of the nanoparticles. In FIG. 3, the distance between the (002) planes is 0.34 nm, which is the same value as the value derived from the X-ray diffraction pattern of the bulk particles, and thus it can be seen that the bulk particle and the nanoparticle are structurally identical. In addition, FIG. 4 shows an electron diffraction pattern image in a selected area of the nanoparticles, and by identifying the (110), (111), (022), (040), and (131) planes in the reciprocal lattice space and calculating the interplanar distance of each plane, it can be confirmed that the nanoparticles are structurally identical to the particles in the bulk state.

The nanoparticles of a blue light-emitting material according to an embodiment may be prepared by mixing a halide of Li, Na, K, Rb, Cs, Mg, Ca, Sr, Ba, or a combination thereof, and a halide of Sc, Y, Al, Gd, Lu, or a combination thereof to form a mixture; heating the mixture at a temperature of from about 500 °C to about 600 °C for a predetermined time under a strongly reducing atmosphere (SRC) to form a heated material; sintering the heated material at a temperature of greater than 600 °C and less than or equal to about 700 °C under a strongly reducing atmosphere to form a sintered material; cooling and pulverizing the sintered material to fine powder; and adding an acidic solution to the fine powder and performing ultrasonication.

The inventors have discovered that the luminescence intensity of the blue light-emitting material represented by Chemical Formula 1 may be different depending on the reduction conditions. That is, when prepared in an inert atmosphere (IC: Inert Condition), such as, for example, Ar gas, the prepared material may exhibit little or very low luminescence intensity. However, when prepared in a mild (or weak) reducing gas atmosphere (MRC: Mild Reduction Condition) that contains a mixture of hydrogen and nitrogen gases, the material exhibits a low luminescence intensity. Further, it can be seen that the material represented by Chemical Formula 1 exhibits a strong luminescence intensity when prepared in a strong reducing atmosphere (SRC: Strong Reduction Condition). That is, the inventors of the present application have discovered that the material represented by Chemical Formula 1, which exhibits very weak luminescence characteristics when prepared in an inert atmosphere, can exhibit relatively strong luminescence characteristics by being prepared in a reducing atmosphere, and further, can be prepared into a blue light-emitting material that exhibits very strong luminescence characteristics by being prepared in a strong reducing atmosphere (SRC). In addition, the inventors of the present application have discovered a method of preparing nanoparticles of the material represented by Chemical formula 1, which has a particle size of nanometers, without changing the luminescence characteristics exhibited by the particles of the material having a particle size of several tens of micrometers prepared by heat treating and sintering in a strongly reducing atmosphere, thereby completing the present invention.

In an embodiment, the blue light-emitting material represented by Chemical Formula 1 may be represented by RbScF₄. RbScF₄ as prepared in a Reference Example described later is in bulk state, i.e., having a particle size of about 30 μm to 50 Am, and has a peak emission wavelength of about 420 nm, a PLQY of 80% or more, a full width at half maximum (FWHM) of the peak emission wavelength of about 25 nm, and an average luminescence lifetime of 80 ns or more, thereby having high stability and excellent luminescence characteristics. According to an embodiment, it is possible to prepare nanoparticles having a particle size of less than 1 μm, for example, several hundred nanometers, of the RbScF₄ particles in bulk state having the excellent luminescence characteristics by adding an acidic solution to the RbScF₄ particles in bulk state and performing ultrasonication.

The heating the mixture under a strongly reducing atmosphere (SRC) may include heating the mixture together with magnesium powder, titanium powder, or a combination thereof, and the same strongly reducing atmosphere may be applied during the sintering process after the heating the mixture.

As described above, the blue light-emitting material can exhibit excellent luminescence characteristics by being prepared under a strongly reducing atmosphere (SRC). For example, the blue light-emitting material may be prepared through a solid-state synthesis method. Here, the “solid-state synthesis method” means that precursor materials for preparing the material represented by Chemical Formula 1 may be mixed in stoichiometric amounts and reacted, but the reaction does not occur in a solution state but in a solid state. Specifically, the precursor materials may be weighed in stoichiometric amounts and mixed in a solid state without adding any solvent to the reaction materials. However, only a small amount of liquid medium may be added for uniform mixing, the solvent used for the mixing may be removed, and a heat treatment and sintering process may be performed to prepare the material.

As a solvent that may be used for the mixing, acetone, alcohol, distilled water, or a mixture thereof may be used, and as an example, acetone may be used. The mixture including the solvent may be put into a mixer, such as, for example, a ball mill or an agate mortar, mixed uniformly, and then the solvent may be removed therefrom. Then, the mixture may be heat-treated and sintered. The solvent may be mixed in an amount of about 100 parts by weight to about 400 parts by weight based on 100 parts by weight of the mixture, but is not limited thereto. When the amount of the solvent is less than 100 parts by weight, uniform mixing may be difficult, and when the amount of the solvent is more than 400 parts by weight, it may take too long to remove the solvent after the mixing.

After the mixing is completed, the solvent may be evaporated and removed, the dried mixture may be pulverized using agate mortar, etc., and then heat-treated at a high temperature in a strongly reducing atmosphere. The strongly reducing atmosphere may be provided by putting the mixture in an alumina crucible, etc., and then heating the mixture in a muffle furnace, and the like, along with metal powders, such as, for example, magnesium powder or titanium powder, and heating them together at a high temperature. The heat treatment may be performed at a temperature of from about 500 °C to about 600 °C, for about from 4 hours to about 6 hours, or for example, about 5 hours.

After completion of the heat treatment, the heated material is naturally cooled, pulverized again using an agate mortar, and the pulverized material may be placed in a tubular furnace and sintered in a strongly reducing atmosphere again at a temperature higher than that of the previous heat treatment, for example, at a temperature of greater than 600 °C and less than or equal to about 700 °C, for about from 5 hours to about 7 hours, or for example, about 6 hours. After the sintering is completed, the sintered material is cooled, and pulverized again using an agate mortar to be a blue light-emitting material in bulk state having an average particle size of tens of micrometers.

The blue light-emitting material in bulk state as prepared above may have a defect or vacancy of an element represented by X in Chemical Formula 1, i.e., for example, fluorine (F), etc., may escape from the layered structure of the material represented by Chemical Formula 1 due to the strongly reducing atmosphere described above. The material represented by Chemical Formula 1 and including the defect may have excellent blue light-emitting characteristics, unlike a material that does not include the defect. As can be seen from the examples described later, the blue light-emitting material in bulk state may be a starting material for preparing nanoparticles of the starting material, which may be applied to a light-emitting device and the like, by adding an acidic solution to the starting material and performing ultrasonication, while not changing the luminescence characteristics, for example, an emission peak wavelength of the blue light-emitting material in bulk state.

Meanwhile, the heat treatment temperature and/or time described above may affect the crystal structure, crystal size, crystallinity, or luminescence efficiency of the prepared blue light-emitting material. For example, if the heat treatment temperature is 500 °C or lower, it is difficult to form crystals, and if the heat treatment temperature is too high (for example, greater than 700 °C), it may be difficult to form crystals from the reactants, crystallinity may be reduced, or agglomeration of crystals may occur, thereby lowering yield and luminescence efficiency of the luminescent material. Therefore, the heat treatment and sintering temperature described above may be performed at an appropriate temperature and time.

The acidic solution may be an aqueous solution of an acid, or an alcohol mixture solution of an acid, and may be prepared by mixing an acid and water, or an acid and an alcohol. For example, the acid may be an inorganic acid such as hydrochloric acid, sulfuric acid, hydrofluoric acid, phosphoric acid, or nitric acid, or an organic acid such as oleic acid or acetic acid, and these acids may be used alone or in combination of two or more. The types of acids that can be used are not limited to those described above, and various inorganic acids or organic acids may be used, and in an example, the acid may be an inorganic acid, for example, hydrochloric acid, hydrofluoric acid, or nitric acid.

The alcohol may include methanol, ethanol, propanol, isopropanol, butanol, etc., and various types of liquid alcohol may be used alone or in combination. The types of alcohol that can be used are not limited to those listed above, and various types of liquid alcohol that can be used in the relevant field may be used.

As can be seen from the examples described later, the size of the nanoparticles of the blue light-emitting material according to an embodiment may be controlled by controlling the time for sonication by adding an acid solution. For example, up to a certain time, the particle size of the nanoparticles produced tends to decrease as the sonication time increases. However, when the sonication time exceeds a certain time, the surface of the produced nanoparticles may be damaged by the acid solution, and in this case, it was found that the damaged particles coagulate with each other, thereby increasing the particle size. Therefore, the ultrasonic treatment time may be appropriately adjusted so that the surface of the nanoparticles being prepared is not damaged and nanoparticles of uniform size are prepared, depending on the concentration of the acid solution used, the type of acid, etc. For example, the ultrasonic treatment time may be from about 10 minutes to about 10 hours, for example, from about 10 minutes to about 8 hours, from about 10 minutes to about 5 hours, from about 30 minutes to about 4 hours, from about 30 minutes to about 3 hours, from about 30 minutes to about 2 hours, or for example, about 1 hour, and is not limited thereto.

In addition, the size and/or luminescence characteristics of the nanoparticles produced may be controlled depending on the type of acid solution used during the sonication process. For example, when sonication is performed for the same period of time with an acid solution of the same concentration, nanoparticles having a smaller particle size and a more uniform particle size may be produced by using an aqueous acidic solution, rather than by using a mixed solution of an acid and an alcohol. Nanoparticles having a smaller and more uniform particle size may have better luminescence characteristics. For example, when sonicated for the same amount of time with an acid solution of the same concentration, the luminescence properties of nanoparticles manufactured using an aqueous solution of the acid may be superior to the luminescence properties of nanoparticles manufactured using a mixed solution of the acid and the alcohol. In an example, the acid may include hydrochloric acid or hydrofluoric acid, and the alcohol may include ethanol.

After adding the acid solution and sonicating, the manufactured nanoparticles may be separated by centrifugation. The nanoparticles separated by centrifugation may be washed by, for example, adding water or alcohol, for example, ethanol, and then centrifuging. The washed nanoparticles may be separated and dried to obtain the final product, the nanoparticles. Alternatively, the separated nanoparticles may be further dispersed in ethanol, etc. for evaluation, etc.

Hereinafter, the embodiments are illustrated in more detail with reference to examples. However, they are exemplary examples of the present invention, and the present invention is not limited thereto. The scope of the present invention can be determined by the claims attached to the specification of the application.

### MODE FOR INVENTION

### Example

### Reference Example: Synthesis of Particles of Blue Light-Emitting Material RbScF₄ in Bulk State

As commercially available starting materials, RbF (Sigma-Aldrich, 99.9%) and ScF₃ (Kojundo, 99.9%) were used without further purification. RbScF₄, a lead-free layered perovskite-like material, was synthesized through the following process.

Specifically, the above two starting materials are stoichiometrically weighed, uniformly mixed with a small amount of acetone in an agate mortar for about 30 minutes, and then dried. For example, about 0.25004 g (1 mol) of RbF and about 1 g of ScF₃ are used per 1 mol of RbScF₄. The obtained powder is placed in an alumina crucible, put in a muffle furnace in which titanium powder and magnesium powder are placed, and heated at a temperature of about 550 °C, for about 5 hours. The amounts of the titanium powder and the magnesium powder were 1 g each per 1 mol of RbScF₄. After the heat treatment, the obtained powder was pulverized using an agate mortar, placed in a tubular furnace, and then placed in the muffle furnace where the titanium powder and magnesium powder were placed and sintered by heating at a temperature of about 650 °C, for about 6 hours. After sintering is complete, the obtained powder is cooled to room temperature, and then pulverized again using an agate mortar into fine particles having a particle size of about from 30 micrometers to 50 micrometers. The obtained blue light-emitting particles are referred to as RbScF₄ in bulk state.

### Example 1: Preparation of Nanoparticles of Blue Light-Emitting Material RbScF₄

200 mg of the bulk RbScF₄ particles prepared in the Reference Example are transferred to a glass vial, and 10 ml of a mixture of 50 ml of deionized water and 10 μL of 0.5 M hydrochloric acid (HCl) is added thereto. The mixture is uniformly mixed for 1 minute using a vortex device, and then ultrasonicated in a sonicator filled with water equal to the height of the solution in the vial for 30 minutes, 1 hour, and 2 hours, respectively. Thereafter, each of the sonicated materials is transferred to a 50 ml centrifuge tube and centrifuged at 8,000 rpm for 10 minutes. Each precipitate is separated and dispersed in 10 ml of water, and centrifuged at 8,000 rpm for 10 minutes. Each of the obtained precipitates is dispersed in 10 ml of ethanol for analysis.

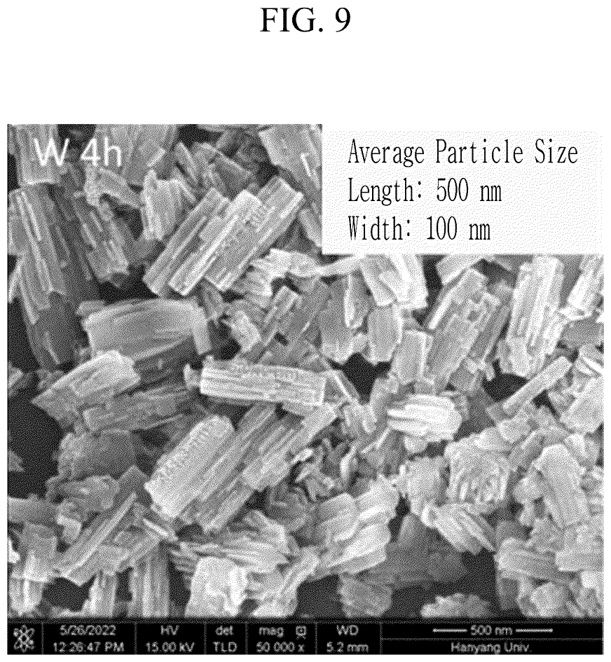

Meanwhile, in order to observe the changes in the size and shape of the nanoparticles as the ultrasonic time increases, the ultrasonic treatment is continued for 4 hours, and a TEM image of the nanoparticles prepared therefrom is shown in FIG. 9.

### Example 2: Preparation of Nanoparticles of Blue Light-Emitting Material RbScF₄

200 mg of the bulk RbScF₄ particles prepared in the Reference Example are transferred to a glass vial, and 10 ml of a mixture of 50 ml of ethanol and 10 μL of 0.5 M hydrochloric acid (HCl) is added thereto. The mixture is uniformly mixed for 1 minute using a vortex device, and then ultrasonicated in a sonicator filled with water equal to the height of the solution in the vial for 30 minutes, 1 hour, and 2 hours, respectively. Thereafter, each of the sonicated materials is transferred to a 50 ml centrifuge tube and centrifuged at 8,000 rpm for 10 minutes. Each precipitate is separated and dispersed in 10 ml of ethanol, and centrifuged at 8,000 rpm for 10 minutes. Each of the obtained precipitates is dispersed in 10 ml of ethanol for analysis.

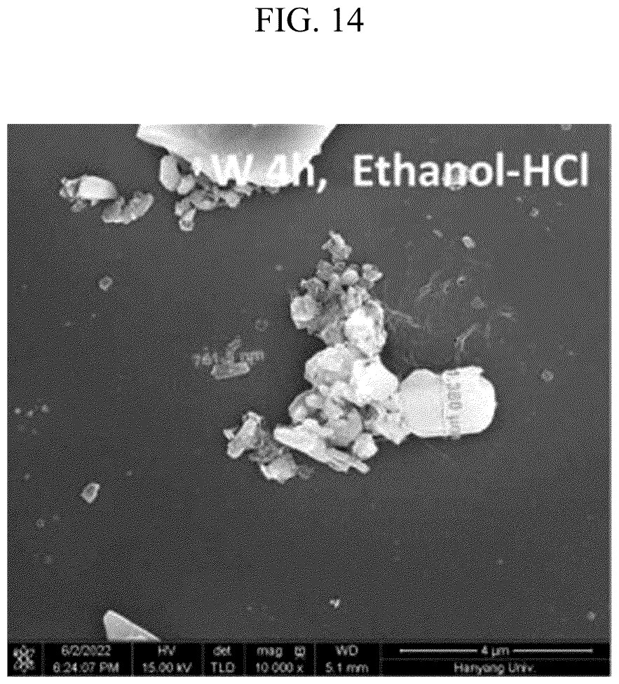

As in Example 1, in order to observe the changes in the size and shape of the nanoparticles as the ultrasonic time increases, the ultrasonic treatment is continued for 4 hours, and a TEM image of the nanoparticles prepared therefrom is shown in FIG. 14.

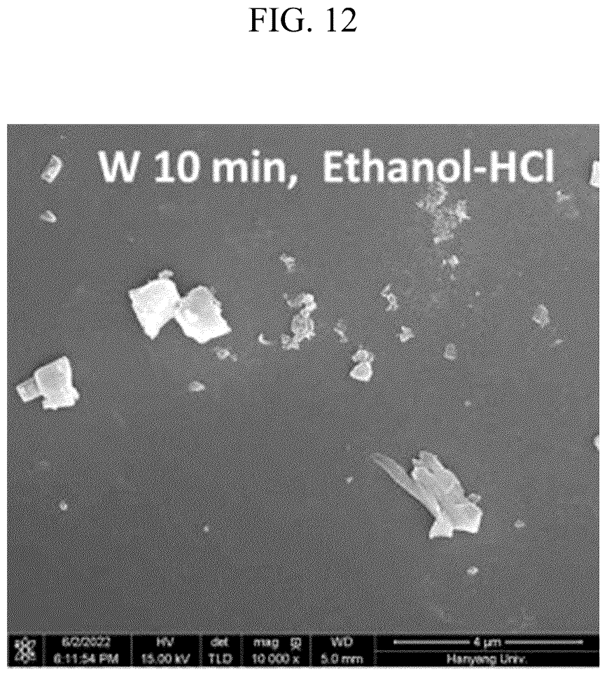

Additionally, nanoparticles were manufactured by adding only ethanol without acid and ultrasonicating for 10 minutes, and nanoparticles were manufactured by adding oleamine instead of acid to a mixed solution of ethanol and hexane and then ultrasonicating for 10 minutes. TEM images of these nanoparticles are shown in FIGS. 12 and 14, respectively.

### Example 3: Preparation of Nanoparticles of Blue Light-Emitting Material RbScF₄

200 mg of the bulk RbScF₄ particles prepared in the Reference Example are transferred to a glass vial, and 10 ml of a mixture of 50 ml of ethanol and 10 μL of 0.5 M hydrofluoric acid (HF) is added thereto. The mixture is uniformly mixed for 1 minute using a vortex device, and then ultrasonicated in a sonicator filled with water equal to the height of the solution in the vial for 10 minutes, 1 hour, and 2 hours, respectively. Thereafter, each of the sonicated materials is transferred to a 50 ml centrifuge tube and centrifuged at 8,000 rpm for 10 minutes. Each precipitate is separated and dispersed in 10 ml of ethanol, and centrifuged at 8,000 rpm for 10 minutes. Each of the obtained precipitates is dispersed in 10 ml of ethanol for analysis.

### Evaluation

### (1) Analysis of the Crystal Structure of Particles Through X-ray Diffraction Patterns and TEM Images, and Confirmation of Particle Morphology

X-ray diffraction patterns of each particles of the blue light-emitting materials according to Reference Example and Example 1 were measured, and the results are shown in FIG. 1. In FIG. 1, the upper graph is the X-ray diffraction pattern of RbScF₄ in bulk state according to Reference Example, and lower graph is the X-ray diffraction pattern of the nanoparticles of RbScF₄, which were prepared by ultrasonicating for 1 hour in Example 1.

From FIG. 1, it can be seen that the two X-ray diffraction patterns of Reference Example and Example 1 are almost same as each other. That is, even if the particle size is reduced to a nanometer degree by adding an acidic solution to the RbScF₄ particles in bulk state, which were manufactured by heat treating and sintering under a strongly reducing atmosphere, and ultrasonicating the same, it can be confirmed that the process of reducing particle size does not change the crystal structure of the RbScF₄ particles in bulk state, and the original crystal structure of the materials is maintained.

The above results can also be confirmed from the lattice pattern and FFT (Fast Fourier Transform) image for the (002) plane of the particles according to Example 1 shown in FIG. 3, and the electron diffraction pattern for a selected area of the particles shown in FIG. 4.

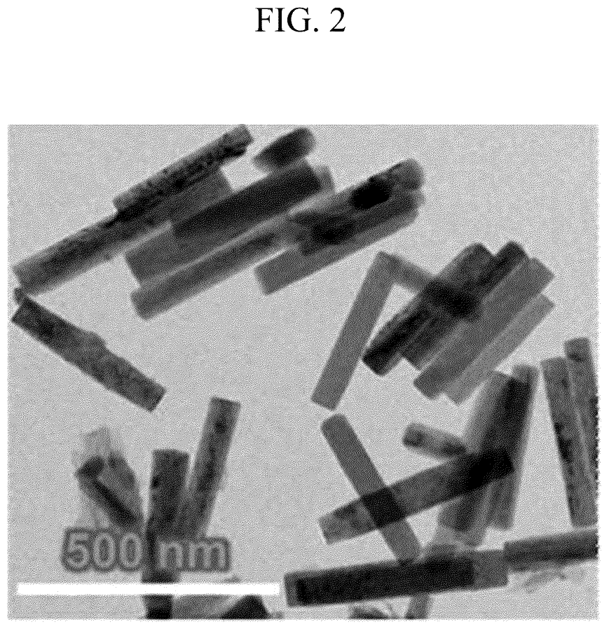

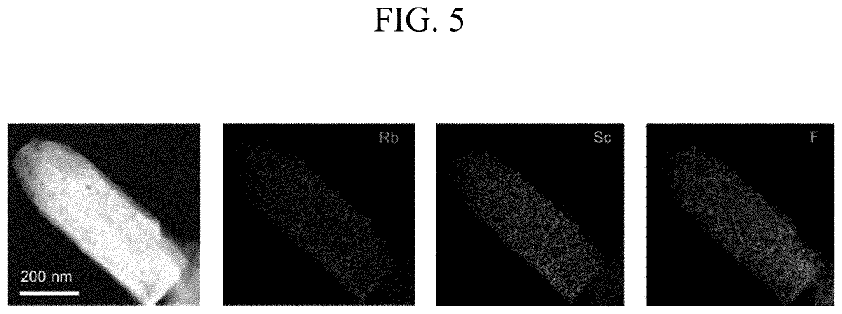

Meanwhile, FIG. 2 is a high-resolution transmission electron microscopy (HR-TEM) image of nanoparticles of RbScF₄ prepared by ultrasonication for 1 hour after addition of an acid solution according to Example 1, and FIG. 5 is a TEM image showing the Ru, Sc, and F element mapping of the nanoparticles. From these figures, it can be seen that the RbScF₄ nanoparticles prepared by ultrasonication for 1 hour in Example 1 are needle-shaped particles having a particle size of about 350 nm to about 400 nm.

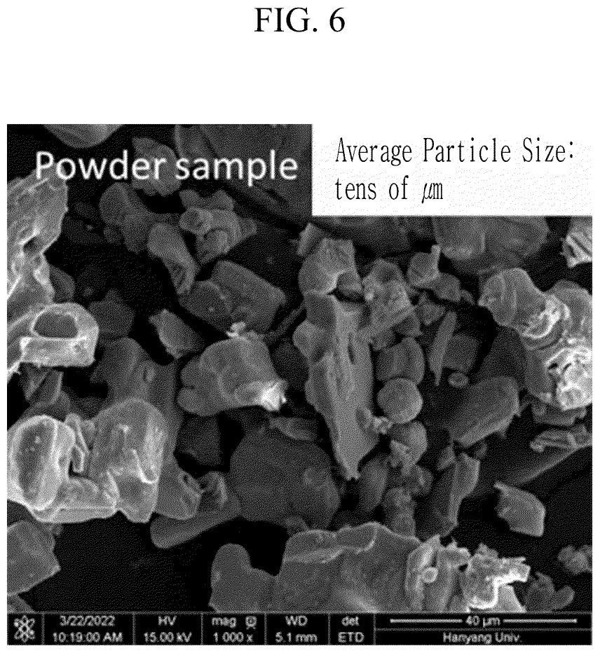

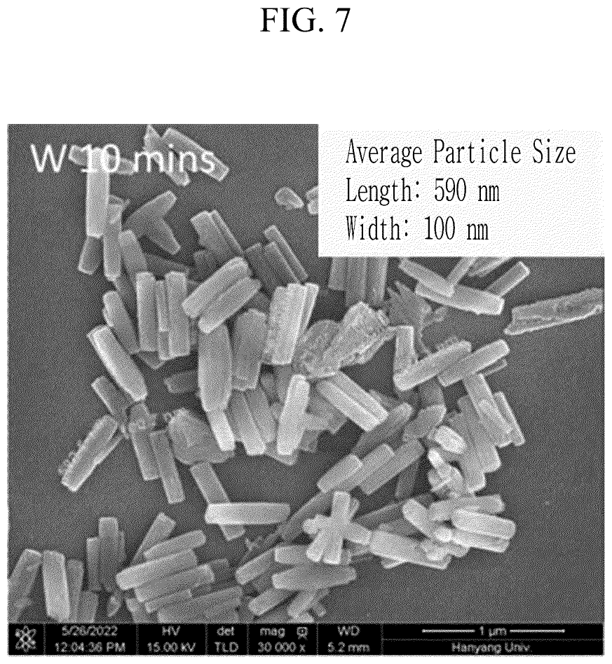

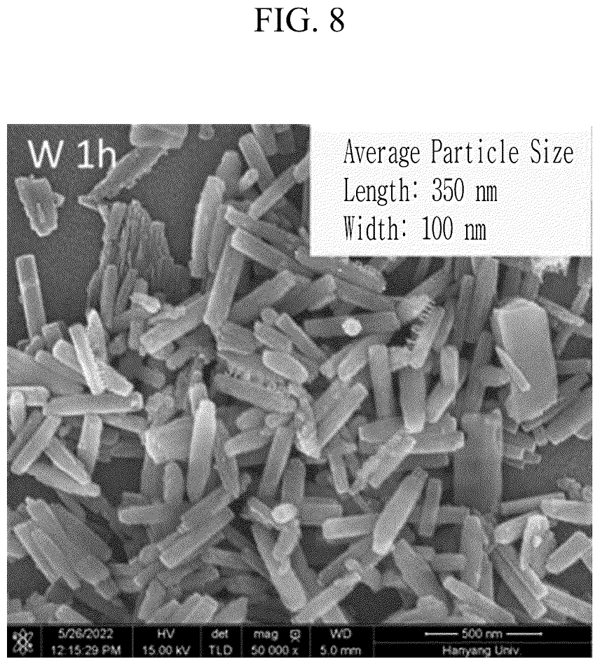

FIG. 6 shows a TEM image of the bulk-sized RbScF₄ particles prepared in Reference Example. FIGS. 7 and 8 are TEM images of nanoparticles prepared by adding an acidic aqueous solution to the bulk-sized RbScF₄ particles according to Reference Example and then ultrasonicating them for 10 minutes and 1 hour, respectively, as described in Example 1.

From FIGS. 6 to 8, it can be seen that by adding an acidic aqueous solution to bulk-sized RbScF₄ particles and then ultrasonicating them, the particle size can be reduced from tens of micrometers to hundreds of nanometers, and the nanoparticles produced therefrom are needle-shaped and have a uniform size and shape. In addition, it can be seen that the longer the ultrasonication time, the smaller the particle size of the produced nanoparticles. However, as can be seen from FIG. 9, when the sonication time is extended to 4 hours, the average particle size of the nanoparticles actually increases compared to when the sonication time is 1 hour. That is, when the sonication time is too long, the acid solution may damage the surface of the manufactured nanoparticles, and the damaged particles may aggregate with each other, causing the nanoparticle size to increase further. Therefore, when light-emitting particles having a size of several tens of micrometers are manufactured into light-emitting particles having a size of several hundred nanometers by the method according to an embodiment, nanoparticles having a particle size of a desired size and a uniform shape can be prepared by ultrasonicating for an appropriate amount of time. The nanoparticles having an appropriate size and a uniform shape according to an embodiment can maintain excellent luminescent characteristics.

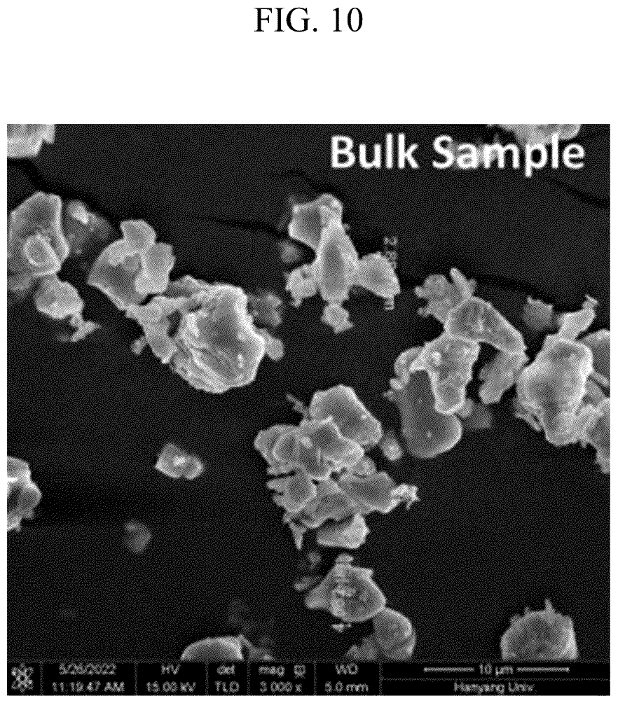

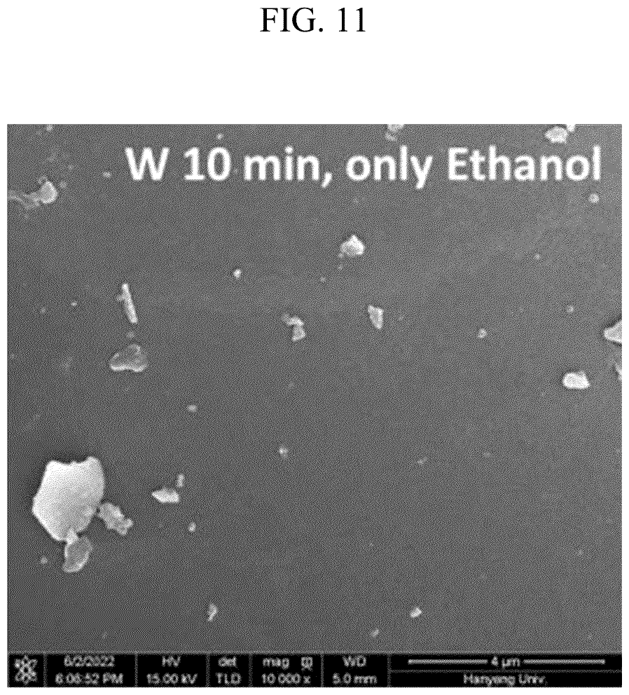

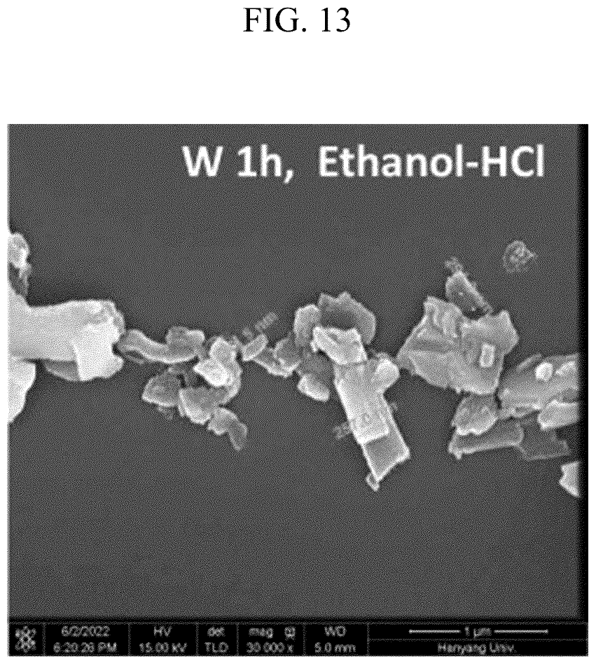

FIG. 10 is a TEM image of the bulk-sized RbScF₄ particles showing a part of FIG. 6, and FIG. 11 is a TEM image of the particles prepared by adding only ethanol to the bulk particles without mixing acid and then ultrasonicating for 10 minutes. In addition, FIGS. 12 and 13 are TEM images of nanoparticles manufactured by adding a mixture of acid and ethanol and then ultrasonicating for 10 minutes and 1 hour, respectively, as described in Example 2.

Referring to FIGS. 11 and 12, FIG. 12 shows particles with a reduced size being pulverized from particles in bulk state by being treated with a mixture of ethanol and hydrochloric acid, compared to the particles shown in FIG. 11, which were treated by only ethanol without hydrochloric acid and sonicated for the same period of time as the particles in FIG. 12. In addition, from FIG. 12 and FIG. 13, it can be seen that as the sonication time increases, nanoparticles with smaller sizes are produced. On the other hand, when the ultrasonic treatment time was maintained for a long time of 4 hours, as shown in FIG. 14, the nanoparticles produced were surface damaged by the acid and then aggregated, showing that nanoparticles with larger particle sizes were produced than those produced in FIG. 12, which were ultrasonicated for 1 hour.

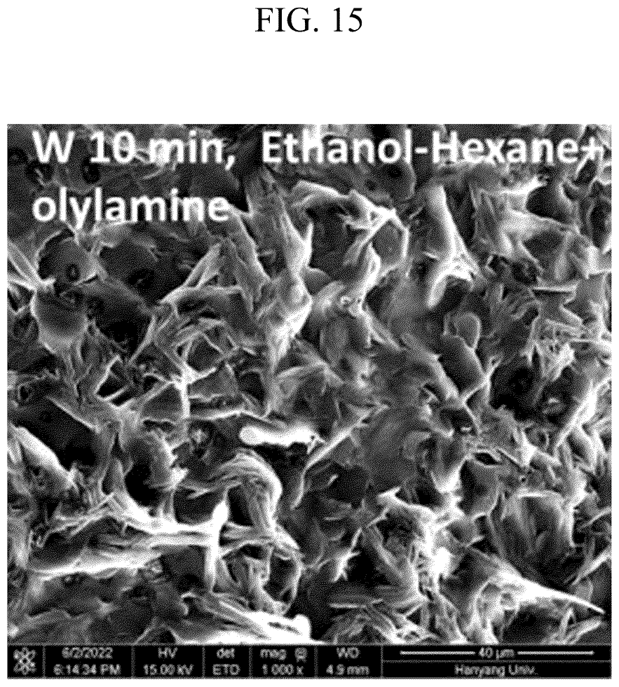

In addition, FIG. 15 is a TEM image showing the result of ultrasonic treatment for 10 minutes by adding a solution containing oleylamine, a basic component, to a mixed solution of ethanol and hexane without adding an acid. From FIG. 15, it can be seen that when an amine-containing solution, not an acidic solution, is added and ultrasonic treatment is performed, the bulk particles are not pulverized into nanoparticles, but rather the particles are formed in an irregularly connected form.

### (2) Analysis of Absorption and Luminescence Characteristics

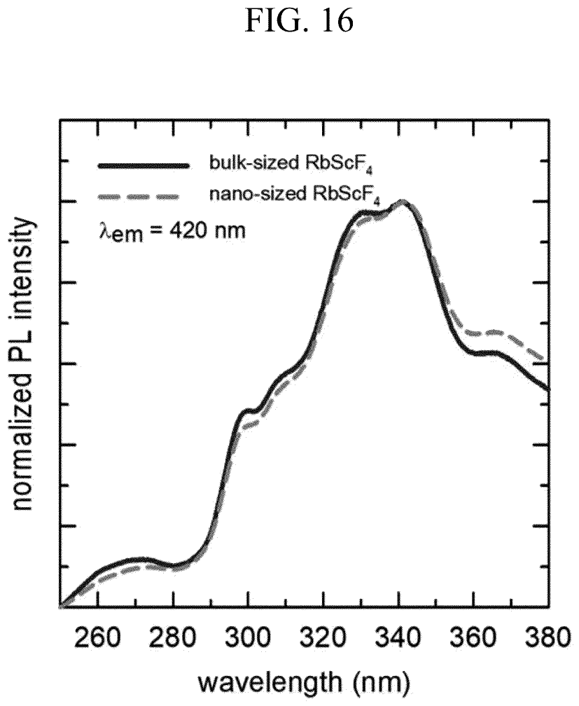

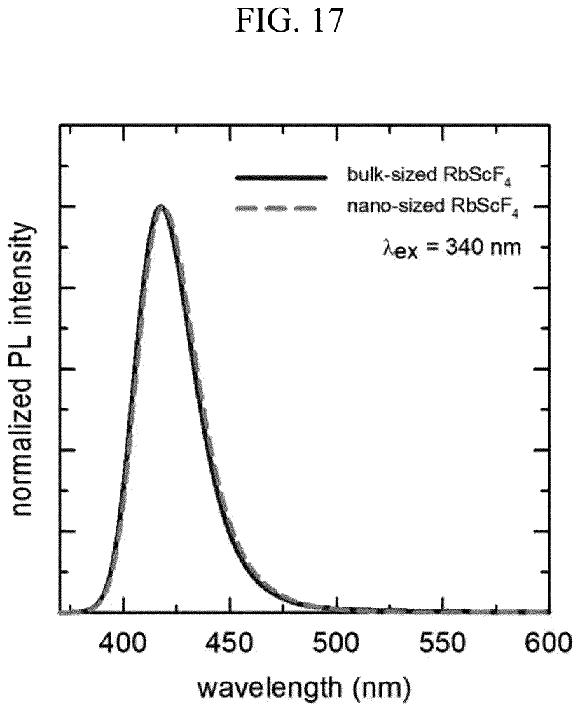

The absorption and luminescence intensities of the bulk-sized RbScF₄ particles according to Reference Example and the nanoparticles prepared by sonication for 1 hour in Example 1 were measured and shown in FIGS. 16 and 17. From FIGS. 16 and 17, it can be confirmed that the absorption and luminescence peaks of the bulk-sized RbScF₄ particles according to Reference Example and the RbScF₄ nanoparticles prepared by sonication for 1 hour in Example 1 are almost the same. That is, it can be seen that the basic absorption and luminescence properties of the bulk-sized RbScF₄ particles according to Reference Example having a particle size of tens of micrometers and the RbScF₄ nanoparticles according to Example 1 having a size of hundreds of nanometers manufactured from the bulk-sized RbScF₄ particles are maintained identically.

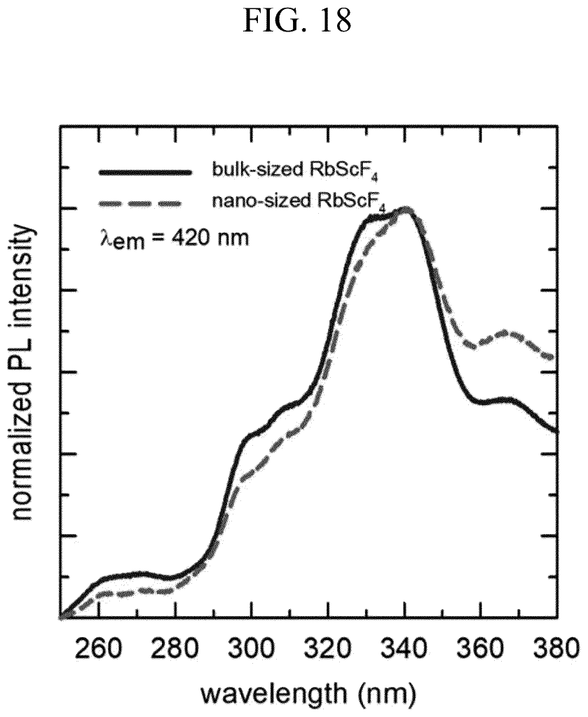

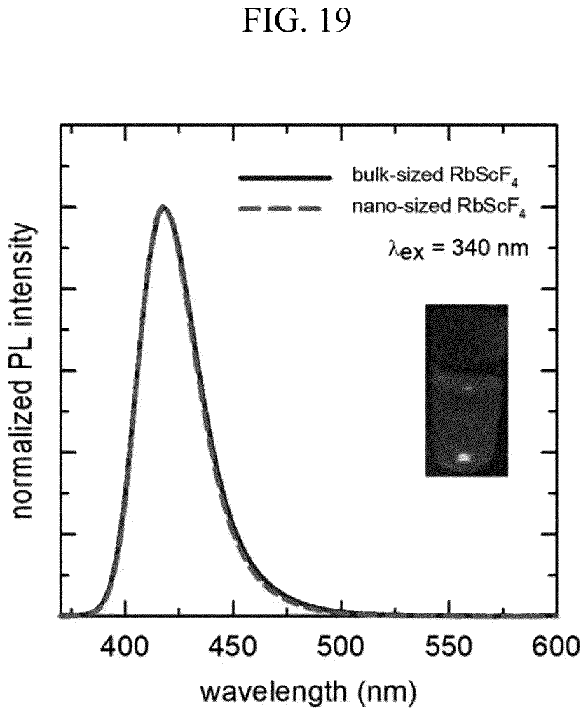

The above characteristics are similarly observed in RbScF₄ nanoparticles manufactured by sonication using a mixture of hydrochloric acid and ethanol according to Example 2. That is, from FIGS. 18 and 19, it can be confirmed that the absorption (FIG. 18) and emission (FIG. 19) peaks of the bulk-sized RbScF₄ particles according to Reference Example and the RbScF₄ nanoparticles manufactured by sonication for 1 hour in Example 2 have almost the same shapes as each other. That is, it can be seen that the basic absorption and luminescence characteristics of the bulk-sized RbScF₄ particles according to Reference Example and the RbScF₄ nanoparticles according to Example 2 having a size of several hundred nanometers manufactured from the bulk-sized RbScF₄ particles are maintained identically.

However, when comparing FIGS. 16 and 18, it can be seen that the absorption peak of the RbScF₄ nanoparticles manufactured according to Example 1 using an aqueous acid solution as the acid solution is more consistent with the absorption peak of the bulk-sized RbScF₄ particles manufactured in Reference Example (see FIG. 16) than with the absorption peak of the RbScF₄ nanoparticles manufactured according to Example 2 using a mixed solution of acid and ethanol as the acidic solution (see FIG. 18). From these results, it can be confirmed that the luminescence properties of nanoparticles manufactured by sonication using an acid-aqueous solution are better than those of nanoparticles manufactured by sonication using a mixed solution of an acid and ethanol. These results can also be expected from the fact that the nanoparticles manufactured by sonication using an acid-aqueous solution as shown in FIGS. 7 and 8 have more uniform shapes than the nanoparticles manufactured by sonication using an acid-ethanol solution as shown in FIGS. 11 and 12.

Meanwhile, the photo attached to the graph of FIG. 19 is a photo showing that the RbScF₄ nanoparticles manufactured in Example 2 emit blue light when irradiated with light of 365 nm using a UV lamp.

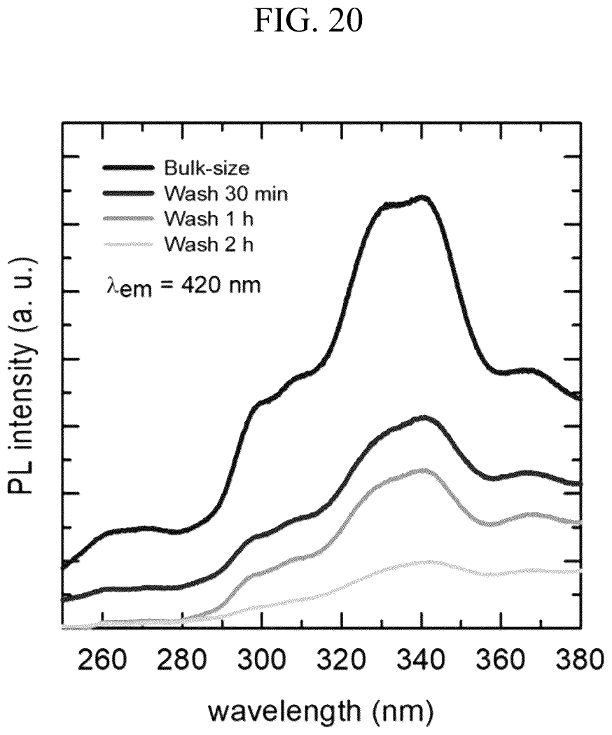

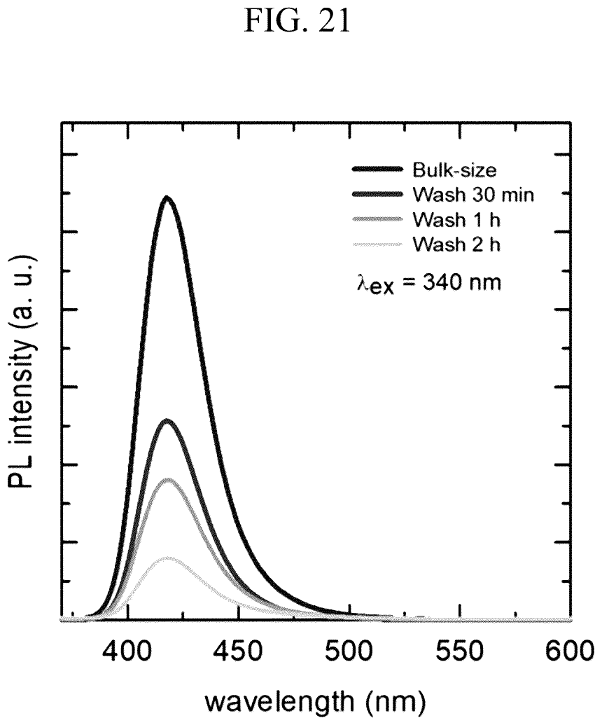

Finally, FIGS. 20 and 21 are graphs comparing the light absorption characteristics and luminescence intensities of bulk RbScF₄ particles according to a Reference Example and nanoparticles manufactured by adding an acid aqueous solution thereto and then ultrasonicating for 30 minutes, 1 hour, and 2 hours, respectively, according to Example 1. From FIGS. 20 and 21, it can be seen that the absorption and luminescence properties of RbScF₄ particles, whose particle size is reduced from the bulk state to the nanometer level, become weaker in intensity as the particle size decreases from the bulk state. That is, it can be seen that the absorption and, thus, luminescence properties of the material are reduced to some extent as the particle size is reduced from tens of micrometers to hundreds of nanometers.

Although the present invention has been described by way of example only and in accordance with the embodiments, the scope of the present invention is not limited thereto, and those skilled in the art will understand that various modifications and variations are possible without departing from the essential characteristics of the present invention. Accordingly, the embodiments of the present specification described above may be implemented separately or in combination, and the protection scope of the present invention should be interpreted by the claims attached, and all technical ideas within a scope equivalent thereto should be interpreted as being included in the scope of the rights of the present invention.

1. Nanoparticles of a blue light-emitting material represented by Chemical Formula 1, the blue light-emitting material having an emission peak wavelength in a range of 380 nanometers to nanometers, upon being excited by an excitation source having a wavelength range of 250 nanometers to 400 nanometers, and an average particle size of less than 1 micrometer:
Chemical Formula 1
AMX₄
wherein, in Chemical Formula 1,
A comprises Li, Na, K, Rb, Cs, Mg, Ca, Sr, Ba, or a combination thereof,
M comprises Sc, Y, Al, Gd, Lu, or a combination thereof, and
X comprises O, F, Cl, Br, I, or a combination thereof.

2. The nanoparticles of the blue light-emitting material according to claim 1,
wherein the nanoparticles of the blue light-emitting material comprise needle-like particles.

3. The nanoparticles of the blue light-emitting material according to claim 1,
wherein the nanoparticles have an aspect ratio of greater than 1 and less than or equal to 100.

4. The nanoparticles of the blue light-emitting material according to claim 1,
wherein the nanoparticles of the blue light-emitting material have an average particle size of greater than or equal to 200 nanometers and less than or equal to 800 nanometers.

5. The nanoparticles of the blue light-emitting material according to claim 1,
wherein the nanoparticles of the blue light-emitting material have a photoluminescent quantum yield of 80% or more.

6. The nanoparticles of the blue light-emitting material according to claim 1,
wherein, in Chemical Formula 1,
A comprises Rb, Cs, Sr, Ba, or a combination thereof,
M comprises Sc, Y, Al, or a combination thereof, and
X comprises F, Cl, Br, or a combination thereof.

7. The nanoparticles of the blue light-emitting material according to claim 1,
wherein Chemical Formula 1 is represented by Chemical Formula 2 or Chemical Formula 3:
Chemical Formula 2
(A₁₋ₓBₓ)(M_{1-y}N_{y})X₄
Chemical Formula 3
(A₁₋₂ₓBₓ)(M_{1-y}N_{y})X₄
wherein, in Chemical Formula 2 and Chemical Formula 3,
A comprises Rb,
B comprises Li, Na, K, Cs, Mg, Ca, Sr, Ba, or a combination thereof,
M comprises Sc,
N comprises Y, Al, Gd, Lu, or a combination thereof,
X comprises O, F, Cl, Br, I, or a combination thereof, and
x is 0.01≤x≤0.10, and y is 0.01≤y≤0.10.

8. The nanoparticles of the blue light-emitting material according to claim 7,
wherein, in Chemical Formula 2 and Chemical Formula 3,
B comprises Cs, and X comprises F, and at least one of O, Cl, Br, and I.

9. The nanoparticles of the blue light-emitting material according to claim 7,
wherein, in Chemical Formula 2 and Chemical Formula 3,
X comprises F and O.

10. The nanoparticles of the blue light-emitting material according to claim 1,
wherein the nanoparticles of the blue light-emitting material have an orthorhombic structure of Cmcm, and diffraction angles (2θ) of a first intensity peak and a second intensity peak, which is lower than the first intensity peak, in a range of 20≤2θ≤30, in an X-ray diffraction pattern.

11. The nanoparticles of the blue light-emitting material according to claim 1,
wherein the nanoparticles of the blue light-emitting material have a diffraction angle (2θ) of a first intensity peak in a range of 26.2≤2θ≤28.2, and a diffraction angle (2θ) of a second intensity peak in a range of 25.8≤2θ≤27.8, in an X-ray diffraction pattern.

12. The nanoparticles of the blue light-emitting material according to claim 1,
wherein the nanoparticles of the blue light-emitting material are nanoparticles of RbScF_{4.}

13. A method of preparing nanoparticles of a blue light-emitting material, the method comprising:
mixing a halide of Li, Na, K, Rb, Cs, Mg, Ca, Sr, Ba, or a combination thereof, and a halide of Sc, Y, Al, Gd, Lu, or a combination thereof to form a mixture;
heating the mixture at a temperature of greater than or equal to 500 °C and less than or equal to 600 °C under a strongly reducing atmosphere to form a heated material;
sintering the heated material at a temperature of greater than 600 °C and less than or equal to 700 °C under a strongly reducing atmosphere to form a sintered material; and
cooling and pulverizing the sintered material, adding an acidic solution thereto, and performing ultrasonication.

14. The method according to claim 13, wherein the heating the mixture or the sintering the material under a strongly reducing atmosphere comprises heating the mixture or sintering the material together with magnesium powder, titanium powder, or a combination thereof.

15. The method according to claim 13, wherein the method further comprises separating nanoparticles by centrifugation after performing the ultrasonication.

16. The method according to claim 13, wherein the method further comprises pulverizing the mixture prior to the heating, pulverizing the heated material after the heating, or pulverizing the mixture prior to the heating and pulverizing the heated material after the heating.

17. The method according to claim 13, wherein the acidic solution comprises an aqueous solution of an acid, or a mixture of an acid and an alcohol.

18. The method according to claim 13, wherein the acid comprises hydrochloric acid, sulfuric acid, phosphoric acid, hydrofluoric acid, nitric acid, or a combination thereof.

19. A light-emitting device comprising nanoparticles of a blue light-emitting material according to claim 1.

20. The light-emitting device according to claim 19,
wherein the light-emitting device comprises a first electrode and a second electrode facing each other, and a light-emitting layer disposed between the first electrode and the second electrode, and
wherein the light-emitting layer comprises the nanoparticles of the blue light-emitting material.
